(19) United States
(12) Patent Application Publication
(10) Pub. No.: US 2011/0147904 A1
(43) Pub. Date: Jun. 23, 2011

(54) SEMICONDUCTOR DEVICE, ELECTRONIC APPARATUS USING THE SEMICONDUCTOR DEVICE, AND METHOD OF MANUFACTURING THE SEMICONDUCTOR DEVICE

(75) Inventor: Hikari SANO, Hyogo (JP)

(73) Assignee: PANASONIC CORPORATION, Osaka (JP)

(21) Appl. No.: 13/037,615

(22) Filed: Mar. 1, 2011

Related U.S. Application Data
(63) Continuation of application No. PCT/JP2009/006461, filed on Nov. 30, 2009.

(30) Foreign Application Priority Data
Jan. 30, 2009 (JP) 2009-020571

(51) Int. Cl. H01L 23/58; H01L 21/50

(52) U.S. Cl. 257/680; 438/116; 257/E23.194; 257/E21.499

(57) ABSTRACT

This invention provides a semiconductor device with increased moisture resistance. The semiconductor device includes: a semiconductor substrate; an optical element provided in a front surface of the semiconductor substrate; a light-transmissive substrate provided above the front surface of the semiconductor substrate; an adhesive layer provided between the front surface of the semiconductor substrate and a front surface of the light-transmissive substrate, and fixing the light-transmissive substrate to the semiconductor substrate; and an insulating film covering a lateral surface of said adhesive layer which is not in contact with the light-transmissive substrate and the semiconductor substrate.

### CROSS REFERENCE TO RELATED APPLICATION(S)

This is a continuation application of PCT application No. PCT/JP2009/006461 filed on Nov. 30, 2009, designating the United States of America.

### BACKGROUND OF THE INVENTION

(1) Field of the Invention

The present invention relates to a semiconductor device, an electronic apparatus using the semiconductor device, and a method of manufacturing the semiconductor device.

(2) Description of the Related Art

Conventionally, there are a variety of semiconductor devices which are used in various types of electronic apparatus, and meet the demands for higher functionality and advanced packaging. Such semiconductor devices include a protective plate via an adhesive layer on a front surface of a semiconductor substrate on which elements are formed, so as to reinforce or protect the element layer.

Here, a brief description is given to a structure of a conventional semiconductor device (an imaging device) shown in FIG. 24 (for example, see International Publication No. WO 2005/022631). FIG. 24 is a cross sectional view of a structure of the conventional semiconductor device.

The semiconductor device includes a semiconductor substrate 31, a semiconductor layer 32 provided in a front surface of the semiconductor substrate 31, and microlenses 33 provided above the semiconductor layer 32. The semiconductor substrate 31 is bonded to a glass substrate 34 via an adhesive material 35 provided on the periphery of the semiconductor substrate 31.

The semiconductor substrate 31 includes through-holes 37 which penetrate the semiconductor substrate 31 between the front and back surfaces. A through-electrode 36 is provided in each through-hole 37. The through-electrode 36 includes a conductive film 39 and a conductive body 40. The conductive body 40 has an opened portion, and also has an exposed portion which serves as an external terminal 40a. At the front surface side of the semiconductor substrate 31, electrode pads 41 and an insulating film 43 are provided.

At the back surface side of the semiconductor substrate 31, an insulating film 38 is provided. An over coat 45 is provided over the insulating film 38 and the portion, other than the external terminal 40a, of the conductive body 40. At the back surface side of the semiconductor substrate 31, an external electrode 42 is provided in contact with the external terminal 40a.

In the semiconductor device shown in FIG. 24, the glass substrate 34 is bonded to the semiconductor substrate 31 as a protective plate. With the protective plate as a support, the semiconductor substrate 31 is thinned, the through-hole 37 is formed, and the through-electrode 36 is formed in the through-hole 37. As a result, it is possible to achieve downsizing and higher backside mountability of the semiconductor device.

### SUMMARY OF THE INVENTION

However, in the conventional semiconductor device, the adhesive material, which bonds the protective plate and the semiconductor substrate, has a low moisture resistance. More specifically, as described above, the protective plate is fixed to the front surface of the semiconductor substrate via the adhesive material, so as to reinforce or protect the semiconductor layer. However, the adhesive material is made of synthetic resin; and thus, the adhesive material is absorbent. As a result, liquid enters the semiconductor device via the adhesive material. This leads to, for example, peeling of the adhesive material from the semiconductor substrate or the protective plate, corrosion of the electrode exposed on the semiconductor substrate, or condensation generated on the microlenses, resulting in deterioration of the characteristics of the semiconductor device.

The present invention has been conceived in view of the problems, and has an object to provide a semiconductor device with increased moisture resistance.

In order to achieve the object, the semiconductor device according to an aspect of the present invention includes: a semiconductor substrate; a semiconductor layer provided in a front surface of the semiconductor substrate; a protective plate provided above the front surface of the semiconductor substrate; an adhesive layer provided between the front surface of the semiconductor substrate and a front surface of the protective plate, the adhesive layer fixing the protective plate to the semiconductor substrate; and a first surface film covering a lateral surface of the adhesive layer, the lateral surface being not in contact with the protective plate and the semiconductor substrate.

According to this structure, the outer edge of the adhesive layer which bonds the protective plate and the semiconductor substrate is covered with a moisture-resistant surface film; and thus, liquid does not enter the semiconductor device via the adhesive layer. Therefore, it is possible to achieve a semiconductor device with increased moisture resistance. As a result, it is possible to prevent the semiconductor layer in the front surface of the semiconductor substrate protected with the protective plate, and the connection terminals nearby from suffering from deterioration due to liquid. It is also possible to prevent the characteristics of the semiconductor device from suffering from deterioration due to the peeling of the adhesive layer from the semiconductor substrate or the protective plate.

Here, it is preferable that the first surface film continuously extends over the lateral surface of the adhesive layer and the semiconductor substrate. Similarly, it is preferable that the first surface film continuously extends over the lateral surface of the adhesive layer onto the protective plate.

According to such structures, the surface film integrally covers the outer edge of the adhesive layer, and the semiconductor substrate and the protective plate which are adjacent to the adhesive layer; and thus, the surface film can be tightly formed on the outer edge of the adhesive layer so that liquid does not enter. As a result, it is possible to prevent liquid from entering the semiconductor device via the adhesive layer, with a high probability.

The present invention may also be implemented as an electronic apparatus which incorporates the semiconductor device.

According to this structure, it is possible to achieve an electronic apparatus with increased moisture resistance.

Furthermore, the present invention may be implemented as a method of manufacturing a semiconductor device which includes: fixing a protective plate to a front surface of a semiconductor substrate via an adhesive layer, the front surface of the semiconductor substrate including a semiconductor layer; and forming a first surface film on a lateral surface of the adhesive layer, the lateral surface being not in contact with the protective plate and the semiconductor substrate. Similarly, the present invention may be implemented as a method of manufacturing a semiconductor device which includes: fixing a protective plate to a front surface of a semiconductor substrate via an adhesive layer, the front surface of the semiconductor substrate including a plurality of semiconductor layers at a plurality of positions; forming a first through-groove penetrating the semiconductor substrate from a back surface to the front surface of the semiconductor substrate; forming a second through-groove by removing the adhesive layer at a bottom of the first through-groove, the second through-groove being continuous to the first through-groove and penetrating the adhesive layer from a front surface, of the adhesive layer, which is in contact with the semiconductor substrate to a back surface, of the adhesive layer, which is in contact with the protective plate; and forming a first surface film on an inner wall of the second through-groove.

According to these structures, it is possible to achieve a method of manufacturing a semiconductor device with increased moisture resistance.

According to the present invention, it is possible to provide a semiconductor device which includes a protective plate and a semiconductor substrate that are bonded to one another via an adhesive layer, with increased moisture resistance, an increased yield rate, and a higher reliability.

### FURTHER INFORMATION ABOUT TECHNICAL BACKGROUND TO THIS APPLICATION

The disclosure of Japanese Patent Application No. 2009-020571 filed on Jan. 30, 2009 including specification, drawings and claims is incorporated herein by reference in its entirety.

The disclosure of PCT application No. PCT/JP2009/006461 filed on Nov. 30, 2009, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a perspective view of an imaging device according to one embodiment of the present invention;

FIG. 2 is a cross sectional view of the imaging device according to the embodiment;

FIG. 3A is a cross sectional view of the imaging device (an enlarged cross sectional view of the region A in FIG. 2) according to the embodiment;

FIG. 3B is a cross sectional view of the imaging device (an enlarged cross sectional view of the region A in FIG. 2) according to the embodiment;

FIG. 4 is a cross sectional view for showing a method of manufacturing the imaging device according to the embodiment;

FIG. 5 is a cross sectional view for showing the method of manufacturing the imaging device according to the embodiment;

FIG. 6 is a cross sectional view for showing the method of manufacturing the imaging device according to the embodiment;

FIG. 7 is a cross sectional view for showing the method of manufacturing the imaging device according to the embodiment;

FIG. 8 is a cross sectional view for showing the method of manufacturing the imaging device according to the embodiment;

FIG. 9 is a cross sectional view for showing the method of manufacturing the imaging device according to the embodiment;

FIG. 10 is a cross sectional view for showing the method of manufacturing the imaging device according to the embodiment;

FIG. 11 is a cross sectional view for showing the method of manufacturing the imaging device according to the embodiment;

FIG. 12 is a cross sectional view for showing the method of manufacturing the imaging device according to the embodiment;

FIG. 13 is a cross sectional view for showing the method of manufacturing the imaging device according to the embodiment;

FIG. 14 is a cross sectional view for showing the method of manufacturing the imaging device according to the embodiment;

FIG. 15 is a cross sectional view for showing the method of manufacturing the imaging device according to the embodiment;

FIG. 16 is a cross sectional view for showing the method of manufacturing the imaging device according to the embodiment;

FIG. 17 is a cross sectional view for showing the method of manufacturing the imaging device according to the embodiment;

FIG. 18 is a cross sectional view for showing the method of manufacturing the imaging device according to the embodiment;

FIG. 19 is a cross sectional view for showing the method of manufacturing the imaging device according to the embodiment;

FIG. 20A is a cross sectional view of a variation of the imaging device according to the embodiment;

FIG. 20B is a cross sectional view of a variation of the imaging device according to the embodiment;

FIG. 20C is a cross sectional view of a variation of the imaging device according to the embodiment;

FIG. 21 is a cross sectional view for showing a variation of the method of manufacturing the imaging device according to the embodiment;

FIG. 22 is a cross sectional view for showing a variation of the method of manufacturing the imaging device according to the embodiment;

FIG. 23A is a cross sectional view for showing a variation of the method of manufacturing the imaging device according to the embodiment;

FIG. 23B is a cross sectional view of a variation of the imaging device according to the embodiment; and

FIG. 24 is a cross sectional view of a structure of a conventional semiconductor device.

### DESCRIPTION OF THE PREFERRED EMBODIMENT(S)

Hereinafter, an imaging device as one embodiment of a semiconductor device according to the present invention is described with reference to the drawings.

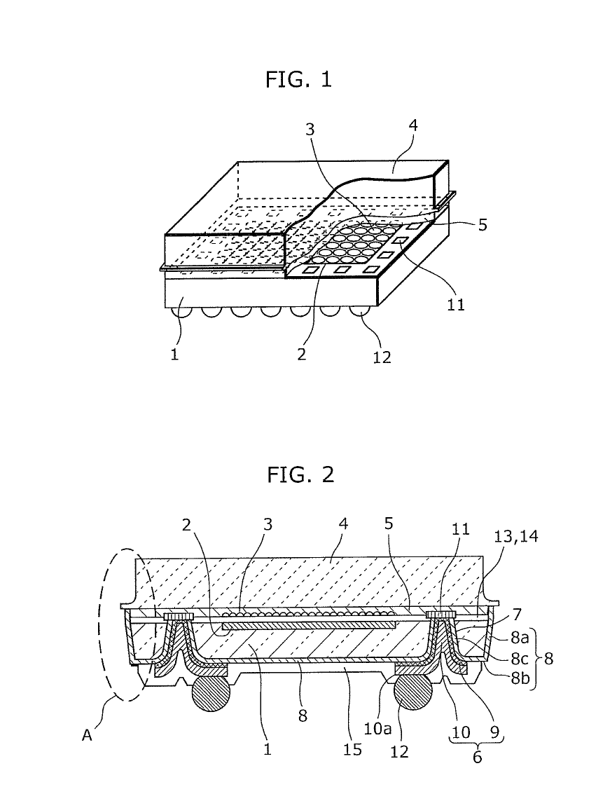

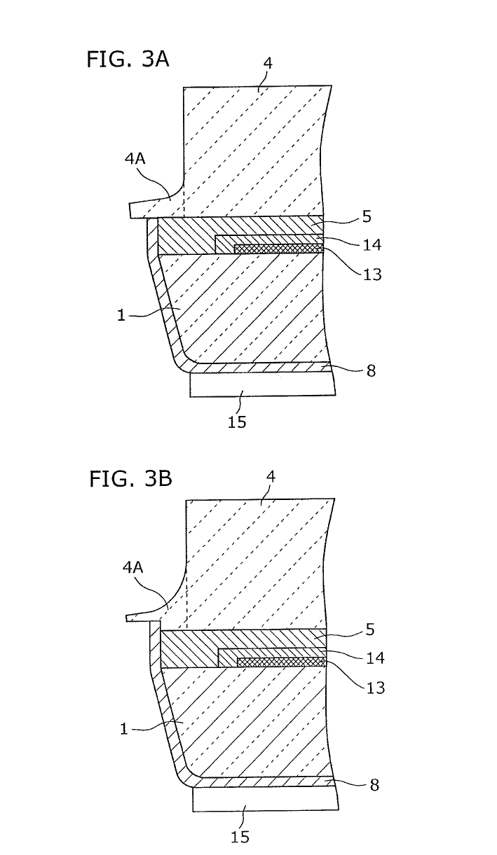

FIG. 1 is a perspective view (partially cutout) of an imaging device according to the embodiment. FIG. 2 is a cross sectional view of the imaging device. FIG. 3A and FIG. 3B are cross sectional views of the imaging device (enlarged cross sectional views of the region A at the periphery of the imaging device in FIG. 2).

As shown in FIG. 1 and FIG. 2, in the imaging device according to the embodiment, a semiconductor layer is formed by a semiconductor process, in a front surface of a semiconductor substrate 1 (top side in FIG. 1 and FIG. 2). More specifically, a plurality of light-receiving elements 2 (an example of optical elements) are formed in the semiconductor layer at the center area of the front surface of the semiconductor substrate 1. At the peripheral surface of the semiconductor substrate 1, a peripheral circuit (not shown) is provided which includes elements for driving and controlling the light-receiving elements 2.

At the peripheral surface, of the semiconductor substrate 1, where the peripheral circuit is provided, cylindrical through-holes 7 are provided penetrating the semiconductor substrate 1 from the front surface to the back surface (bottom side in FIG. 1 and FIG. 2) of the semiconductor substrate 1. As shown in FIG. 2, in each through-hole 7, a cylindrical insulating film 8 is provided in contact with and covering the inner wall of the through-hole 7. A through-electrode 6 is provided in the through-hole 7 and in contact with the inner wall of the insulating film 8.

The through-electrode 6 includes a cylindrical conductive film 9 and a cylindrical conductive body 10 both of which are in the through-hole 7. The conductive body 10 is in contact with the conductive film 9 and is thicker than the conductive film 9. The conductive body 10 has an exposed portion which serves as an external terminal 10a. The conductive film 9 of the through-electrode 6 is electrically connected to an electrode 11 which is connected to the peripheral circuit at the front surface of the semiconductor substrate 1.

As shown in FIG. 2 and FIG. 3A, the front surface of the semiconductor substrate 1 is entirely covered with an insulating layer 13 except the opening which is between the electrode 11 and the through-hole 7 and in which a connection portion of the through-electrode 6 is formed. The insulating layer 13 includes conductive bodies (not shown) which electrically connect the peripheral circuit (element) and the electrode 11. At the front surface side of the semiconductor substrate 1, a surface protective film 14 is provided as an insulating layer which covers the top surface of the insulating layer 13. The surface protective film 14 has an opening at the surface of the electrode 11. The opening is, for example, used for a test terminal in a semiconductor process. Here, the insulating layer 13 is generally formed of, for example, one or more layers of CVD (chemical vapor deposition) films of silicon oxide. The surface protective film 14 is generally formed of, for example, one or more layers of CVD films of silicon nitride. It may be that the electrode 11 is covered with the surface protective film 14. Such structure is effective to reinforce the electrode 11 in the forming process of the through-electrode 6. It may also be that the electrode 11 is formed inside the insulating layer 13. Such structure thins the insulating layer between the through-hole 7 and the electrode 11, thereby facilitating the process where a part of the insulating layer is removed to expose the surface of the electrode 11 at the bottom of the through-hole 7.

On the front surface of the surface protective film 14 deposited between the semiconductor substrate 1 and the adhesive layer 5, microlenses 3 are provided at positions corresponding to respective light-receiving elements 2. It may be that a color filter is provided between the microlenses 3 and the surface protective film 14. A light-transmissive substrate 4, such as a glass substrate, is provided as a protective plate above the semiconductor substrate 1, more specifically, above the microlenses 3. At least the bottom side of the periphery of the light-transmissive substrate 4 is bonded to the front surface of the semiconductor substrate 1 via the adhesive layer 5.

The adhesive layer 5 is formed of a film including materials, such as acrylic transparent resin, having a refractive index adjusted to be substantially equivalent to that of the light-transmissive substrate 4. The adhesive layer 5 entirely covers the front surface of the semiconductor substrate 1. Accordingly, it is possible to equalize stress loading during the process. The adhesive layer 5 is disposed between the front surface of the semiconductor substrate 1 and a front surface of the light-transmissive substrate 4 to fix the light-transmissive substrate 4 to the semiconductor substrate 1. In the light-receiving devices, there is a concern that the adhesive layer 5 is deteriorated by light. Thus, it may be that the adhesive layer 5 is formed only on the region, of the front surface of the semiconductor substrate 1, where the peripheral circuit is provided, and that the region, of the front surface of the semiconductor substrate 1, where the light-receiving elements 2 are formed is opened.

As shown in FIG. 2 and FIG. 3A, the back side and lateral side (outer edge side) of the semiconductor substrate 1 and the lateral side (outer edge side) of the adhesive layer 5 are entirely covered with the insulating film 8 except the portions where the through-electrodes 6 are formed. The bottom sides of the insulating film 8 and the conductive body 10 are entirely covered with the over coat 15 except the portion where the external terminal 10a is formed and the insulating film 8 that is formed on the lateral side of the semiconductor substrate 1.

At the back side of the semiconductor substrate 1, external electrodes 12 are respectively provided in contact with the external terminals 10a. The external electrode 12 is connected to the peripheral circuit provided at the front surface side of the semiconductor substrate 1, via the through-electrode 6 and the electrode 11, so that the light-receiving elements 2 are electrically connected to the peripheral circuit.

The light-transmissive substrate 4 is used for preventing dust from adhering on the light-receiving elements 2 and the microlenses 3 and from appearing in an image. The light-transmissive substrate 4 further protects the light-receiving elements 2 and the microlenses 3, prevents the microlenses 3 and the color filter from suffering from deterioration due to liquid, and reinforces the semiconductor substrate 1 during processing and handling.

It is preferable that the insulating layer 13 has openings at the regions near the lateral sides of the semiconductor substrate 1 (scribe regions). By doing so, it is not necessary to remove the insulating layer 13 before removing the adhesive layer 5 at the time of forming, at the scribe regions, through-grooves which reach the light-transmissive substrate 4 in the later-described manufacturing process.

It is also preferable that the surface protective film 14 has openings at the scribe regions of the semiconductor substrate 1. By doing so, it is not necessary to remove the surface protective film 14 at the time of forming, at the scribe regions, the through-grooves which reach the light-transmissive substrate 4.

A basic structure of the imaging device according to the embodiment has been described. In the following, characteristics of the imaging device according to the embodiment will be described.

As shown in FIG. 2, the insulating film 8 includes: a first insulating film 8a which is in contact with air and covers the lateral side, of the adhesive layer 5, which is not in contact with the light-transmissive substrate 4 and the semiconductor substrate 1; a second insulating film 8b which is provided on the back surface of the semiconductor substrate 1 and bonded to the first insulating film 8a; and a third insulating film 8c which is provided between the inner wall of the through-hole 7 and the conductive film 9, and bonded to the insulating layer 13 and the second insulating film 8b.

It is preferable that the first insulating film 8a, the second insulating film 8b, and the third insulating film 8c are integrally formed as a continuous film. This increases mechanical strength of the insulating film 8 and prevents the insulating film 8 from dropping from the lateral side of the adhesive layer 5.

It is preferable that the first insulating film 8a is chemically bonded to the semiconductor substrate 1 and the light-transmissive substrate 4. In this case, the boundary plane between the insulating film 8 and the semiconductor substrate 1 or the light-transmissive substrate 4 does not serve as an entry pathway for liquid. As a result, moisture prevention efficiency is increased.

For example, a substrate including silicon, such as a silicon substrate, is used for the semiconductor substrate 1. For the light-transmissive substrate 4, a substrate including silicon, such as a silicate glass plate, is used. For the insulating film 8, a silicon oxide film is used. The insulating film 8 is formed of, for example, a CVD film. The CVD film of silicon oxide has a plane with a fine texture and a high moisture resistance. In addition, the CVD film of silicon oxide can be mechanically and chemically integrated with the silicon substrate and the silicate glass plate.

As shown in FIG. 3A, the outer edge of the adhesive layer 5 is covered with the insulating film 8 that is moisture resistant and has a low water absorption rate. The insulating film 8 continuously extends over the lateral side of the adhesive layer 5 and the lateral side of the semiconductor substrate 1, and onto the front surface of the light-transmissive substrate 4 (bottom side in FIG. 3A). The insulating film 8 at least closely contacts with the lateral surface, of the semiconductor substrate 1, which is adjacent to the adhesive layer 5, and contacts with the front surface of the light-transmissive substrate 4. Thus, the outer edge of the adhesive layer 5 is covered with the insulating film 8, and the adhesive layer 5 is sealed with the insulating film 8. Accordingly, it is possible to prevent liquid from entering from the lateral side of the adhesive layer 5. As a result, even when the adhesive layer 5 is formed of a hygroscopic organic film, such as synthetic resin, liquid does not enter the adhesive layer 5. Thus, it is possible to prevent peeling of the adhesive layer 5 from the semiconductor substrate 1 or the light-transmissive substrate 4, corrosion of the electrode 11, and condensation generated on the microlens 3, thereby preventing deterioration of the characteristics of the imaging device.

As shown in FIG. 3A, the insulating layer 13 on the semiconductor substrate 1 has openings at the peripheral surface of the semiconductor device 1. The adhesive layer 5 is in contact with the front surface of the semiconductor substrate 1 at the openings of the insulating layer 13.

As shown in FIG. 3A, the light-transmissive substrate 4 has a periphery 4A that is thinner than the portions of the light-transmissive substrate 4 other than the periphery 4A. The periphery 4A decreases its thickness toward its edge. The periphery 4A has a flat lateral surface (outer edge surface). The periphery 4A is provided above the periphery of the semiconductor substrate 1. The periphery 4A partially protrudes out from the lateral surface of the semiconductor substrate 1.

As shown in FIG. 3B, it is preferable that the periphery 4A of the light-transmissive substrate 4 has, at the front surface (bottom side in FIG. 3A), a step that is lower than the front surface, so that the insulating film 8 continuously extends over the lateral side of the adhesive layer 5 and the front and lateral surfaces of the step. Since, in this structure, the insulating film 8 provided on the outer edge of the adhesive layer 5 has a part which protrudes toward the light-transmissive substrate 4, the adhesive layer 5 closely contacts the light-transmissive substrate 4. As a result, adhesion between the insulating film 8 and the light-transmissive substrate 4 is increased, and moisture prevention efficiency of the imaging device is increased.

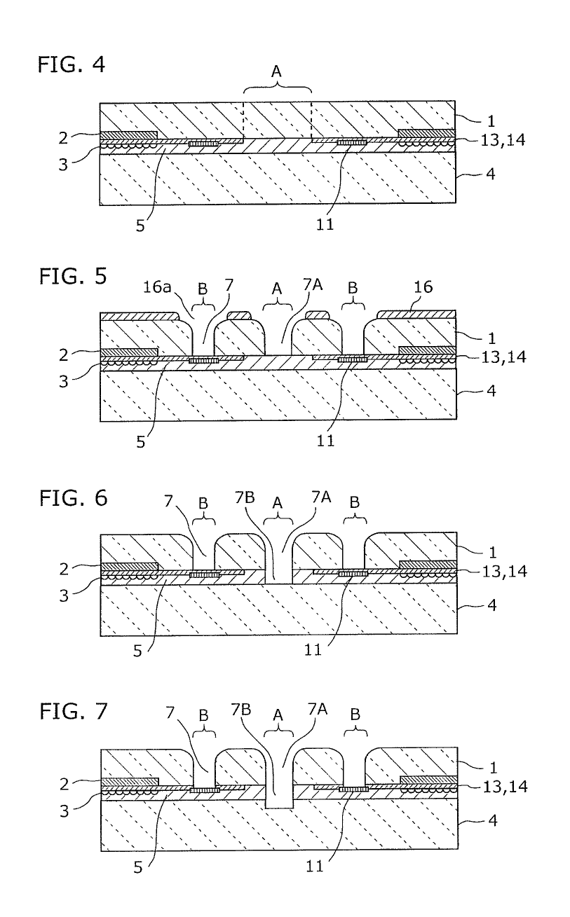

Next, a method of manufacturing the imaging device according to the embodiment will be described with reference to the cross sectional views in FIG. 4 to FIG. 19.

In FIG. 4 to FIG. 13, the semiconductor substrate 1 is illustrated upside down relative to FIG. 1 to FIG. 3B; and thus, the top side of the semiconductor substrate 1 in FIG. 1 to FIG. 3B is the back side in FIG. 4 to FIG. 13, and the back side of the semiconductor substrate 1 in FIG. 1 to FIG. 3B is the top side in FIG. 4 to FIG. 13.

In the method of manufacturing the imaging device according to the embodiment, the semiconductor substrate 1 is formed by dicing, into individual chips, the large semiconductor substrate 1 (semiconductor wafer) on which the light-receiving elements 2 are formed at a predetermined interval. The light-transmissive substrate 4 is also formed by dicing the large light-transmissive substrate 4 into individual chips. In order to avoid confusion in the description, the semiconductor wafer is referred to as the semiconductor substrate 1, and the large light-transmissive substrate 4 is also referred to as the light-transmissive substrate 4.

First, the light-receiving elements 2 are formed in the front surface of the semiconductor substrate 1. The microlenses 3, the insulating layer 13, and the surface protective film 14 are formed above the semiconductor substrate 1. The electrodes 11 are formed on the insulating layers 13.

Next, as shown in FIG. 4, the light-transmissive substrate 4 is fixed via the adhesive layer 5 to the front surface, of the semiconductor substrate 1, (bottom side in FIG. 4) provided with the light-receiving elements 2, the microlenses 3, the electrodes 11, the insulating layer 13, and the surface protective film 14. The semiconductor substrate 1 is then thinned with the light-transmissive substrate 4 as a support.

Next, as shown in FIG. 5, on the back surface of the semiconductor substrate 1 (top side in FIG. 5), a mask layer 16 is formed which has openings 16a at through-electrode forming sections B and a separation section for singulation (scribe region) A. Subsequently, the semiconductor substrate 1 at the openings 16a is removed so that the through-holes 7 and a first through-groove 7A are simultaneously formed penetrating the semiconductor substrate 1 from the back to the front surface thereof. The first through-groove 7A is formed along the entire perimeter of the singulated semiconductor substrate 1.

Next, as shown in FIG. 6, the adhesive layer 5 at the bottom of the first through-groove 7A is removed to expose the light-transmissive substrate 4. As a result, a second through-groove 7B is formed. The second through-groove 7B is continuous to the first through-groove 7A and penetrates the adhesive layer 5 from the front surface, of the adhesive layer 5, which contacts the semiconductor substrate 1 (top side in FIG. 6) to the back surface, of the adhesive layer 5, which contacts the light-transmissive substrate 4 (bottom side in FIG. 6). The mask layer 16 remaining on the back surface of the semiconductor substrate 1 may be removed at the same time of the removal of the adhesive layer 5. By doing so, the removing process of the remaining mask layer 16 may be omitted. It may also be that the remaining mask layer 16 is removed after removing one of the semiconductor substrate 1, the adhesive layer 5, and the insulating film 8 at the opening 16a. For example, plasma ashing or wet ashing is used for the removal of the remaining mask layer 16.

Next, as shown in FIG. 7, the insulating layer 13, which is at the bottom of the through-hole 7 and between the through-hole 7 and the electrode 11, is opened to expose the electrode 11. Here, for example, it is assumed that the light-transmissive substrate 4 and the insulating layer 13 are formed of materials having similar properties, such as the case where a silicate glass plate is used for the light-transmissive substrate 4, and a silicon oxide film is used for the insulating layer 13. In this case, at the same time of opening the insulating layer 13, the light-transmissive substrate 4 that is at the bottom of the second through-groove 7B is also removed so that a step (groove) is formed at the front surface (top side in FIG. 7) of the light-transmissive substrate 4.

In the case where the insulating layer 13 is provided at the scribe region A, it is necessary to remove the insulating layer 13 at the bottom of the first through-groove 7A and the through-hole 7 before removing the adhesive layer 5. However, in this case, removing the insulating layer 13 first leads to removing the adhesive layer 5 with the electrode 11 being exposed. This generates a concern of a damage imposed on the electrode 11. In particular, for example, a conductive film, such as Al, is generally used for the electrode 11. However, Al is chemically reactive. In view of this point, it is preferable to remove the insulating layer 13 after removing the adhesive layer 5 with the electrode 11 being protected by the insulating layer 13. Thus, it is preferable that the insulating layer 13 has an opening at the scribe region A.

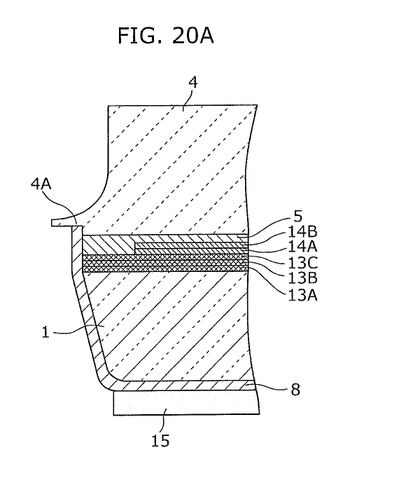

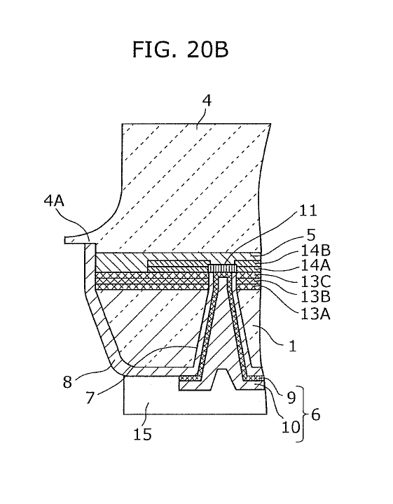

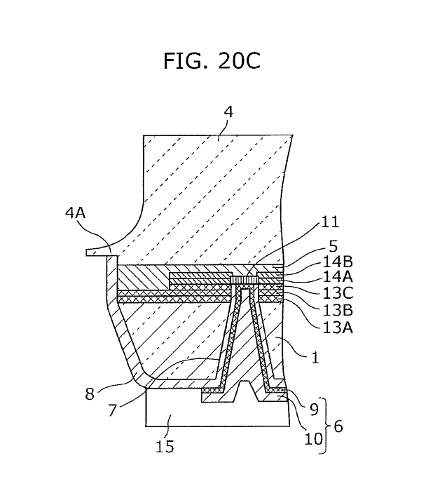

In the case where each of the insulating layer 13 and the surface protective film 14 has a film stack structure, it may be that only one or more films in the insulating layer 13 and the surface protective film 14 has openings at the scribe region A. For example, as shown in FIG. 20A, it is assumed that the insulating layer 13 has a stack structure including the insulating layers 13A, 13B, and 13C from the bottom, and the surface protective film 14 has a stack structure including the surface protective films 14A and 14B from the bottom. In such a case, it may be that only the surface protective films 14A and 14B are opened at the scribe region A, while the insulating layers 13A, 13B, and 13C remains unopened. According to such structure, it is possible to eliminate the process of opening the surface protective film 14 from the process of forming, at the scribe region A, the through-groove which extends from the back surface of the semiconductor substrate 1 to the front surface of the light-transmissive substrate 4. In addition, in the process of stacking films of the insulating layer 13 and the surface protective film 14 during the semiconductor process, it is possible to keep flatness of the films at the scribe region A.

In the case where the electrode 11 is provided which is connected to the through-electrode 6, it is preferable that, of the films of the insulating layer 13 and the surface protective film 14, at least the films at the levels not lower than the forming layer of the electrode 11 (the level where the electrode 11 is formed) has an opening at the scribe region A. For example, as shown in FIG. 20B, it is assumed that: the insulating layer 13 has a stack structure including the insulating layers 13A, 13B, and 13C from the bottom; wiring including the electrode 11 is formed above the insulating layer 13C; and the protective film 14, which has a stack structure of the surface protective films 14A and 14B, is formed on the insulating layer 13C. In such a case, the surface protective films 14A and 14B, which are not lower than the forming layer of the electrode 11, are opened at the scribe region A. According to such structure, it is possible to simultaneously form the openings of the insulating layers 13A to 13C at the bottom of the through-hole 7 where the through-electrode 6 is formed and at the bottom of the first through-groove 7A at the scribe region A.

It is also preferable that, of the films of the insulating layer 13, at least the films above which the electrode 11 is formed, that is, at least one or more films at the levels lower than the forming layer of the electrode 11 are opened at the scribe region A. For example, as shown in FIG. 20C, it is assumed that the insulating layer 13 has a stack structure of the insulating layers 13A, 13B, and 13C from the bottom, and the surface protective film 14 has a stack structure of the surface protective films 14A and 14B. In such a case, the surface protective films 14A and 14B that is at the levels not lower than the electrode 11 and the insulating layer 13C above which the electrode 11 is formed are opened at the scribe region A. According to the structure, the electrode 11 is covered with the insulating layer 13C in the process of removing the adhesive layer 5 at the bottom of the first through-groove 7A, thereby protecting the electrode 11. In this case, it is preferable to remove the insulating layers 13A and 13B at the bottom of the first through-groove 7A and the through-hole 7 while leaving only the insulating layer 13C that is in contact with the electrode 11, remove the adhesive layer 5 at the bottom of the first through-groove 7A, and then remove the remaining insulating layer 13 that is in contact with the electrode 11 at the bottom of the through-hole 7.

Furthermore, it is preferable to form the first through-groove 7A and the second through-groove 7B, and successively remove the insulating film 8, by dry etching; however, wet etching may be performed as necessary. For the dry etching and wet etching, appropriate etching gas and etching liquid are selected.

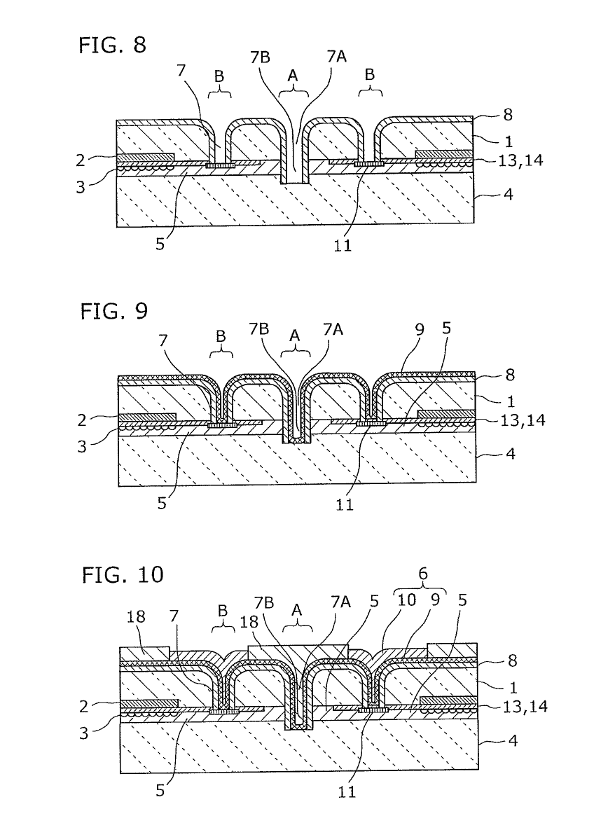

Next, as shown in FIG. 8, the insulating film 8 is formed on the inner walls of the first through-groove 7A, the second through-groove 7B, and the through-holes 7, and on the back surface of the semiconductor substrate 1 (top side in FIG. 8), at the same time. Accordingly, the insulating film 8 is formed on the lateral side, of the adhesive layer 5, which does not contact the light-transmissive substrate 4 and the semiconductor substrate 1. The insulating film 8 further extends continuously over the adhesive layer 5 onto the step of the light-transmissive substrate 4. For example, the insulating film 8 is formed in the following manner: a CVD film of silicon oxide is integrally formed over the inner walls of the first through-groove 7A, the second through-groove 7B and the through-hole 7, and the entire back surface of the semiconductor substrate 1; and then, the CVD film at the bottom of the second through-groove 7B and the through-hole 7 are removed at the same time to expose the electrode 11 and the light-transmissive substrate 4.

It is preferable to successively perform the processes shown in FIG. 5 to FIG. 8, for example, by using a dry process, and a same transporting and control systems with different gases and chambers. This reduces the required time between the respective processes and increases productivity.

Next, as shown in FIG. 9, the conductive film 9 having one or more layers is formed by sputtering, over the inner walls of the through-holes 7, the first through-groove 7A and the second through-groove 7B and the back surface of the semiconductor substrate 1 (top side in FIG. 9).

Next, as shown in FIG. 10, the conductive body 10 is formed by plating. Accordingly, the through-electrodes 6 are formed so as to establish conduction between the conductive film 9 and the electrodes 11. Here, in order to prevent the conductive body 10 from being formed in the first through-groove 7A and the second through-groove 7B by the plating, a resist mask 18 is formed in the first through-groove 7A to fill the opening thereof.

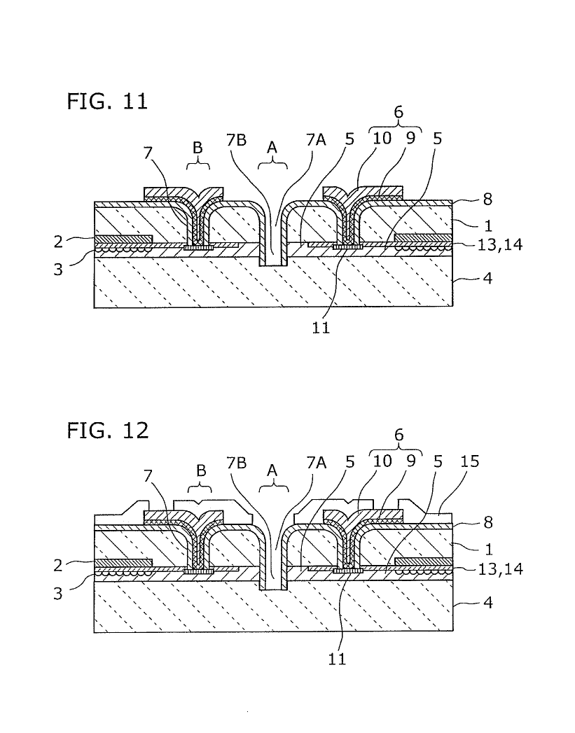

Next, as shown in FIG. 11, after removing the resist mask 18, the conductive film 9 at the back surface of the semiconductor substrate 1 (top side in FIG. 11) and on the inner walls of the first through-groove 7A and the second through-groove 7B is removed by the etching using the conductive body 10 as a mask.

Next, as shown in FIG. 12, an over coat 15 is provided above the back surface of the semiconductor substrate 1 (top side in FIG. 12).

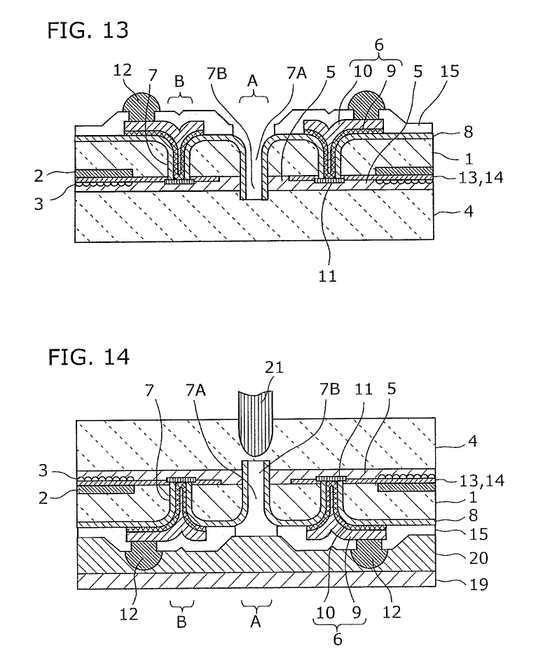

Next, as shown in FIG. 13, the external electrode 12 is provided on the conductive body 10 of the through-electrode 6, to electrically connect the through-electrode 6 and the external electrode 12.

Next, as shown in FIG. 14, the semiconductor substrate 1 is turn upside down. The adhesive layer 20 and the over coat 15 are bonded such that the external electrode 12 is embedded in the adhesive layer 20 on the dicing sheet 19. Under this condition, dicing is performed, with a dicing blade 21, on the light-transmissive substrate 4 at the scribe region A, that is, the portion of the light-transmissive substrate 4 constituting the bottom of the second through-groove 7B. The dicing is performed from the back surface of the light-transmissive substrate 4 (top side in FIG. 14) up to near the second through-groove 7B. As a result, the portion of the light-transmissive substrate constituting the bottom of the second through-groove 7B is removed. The maximum width of a predetermined region of the removed portion is greater than the width of the bottom of the second through-groove 7B.

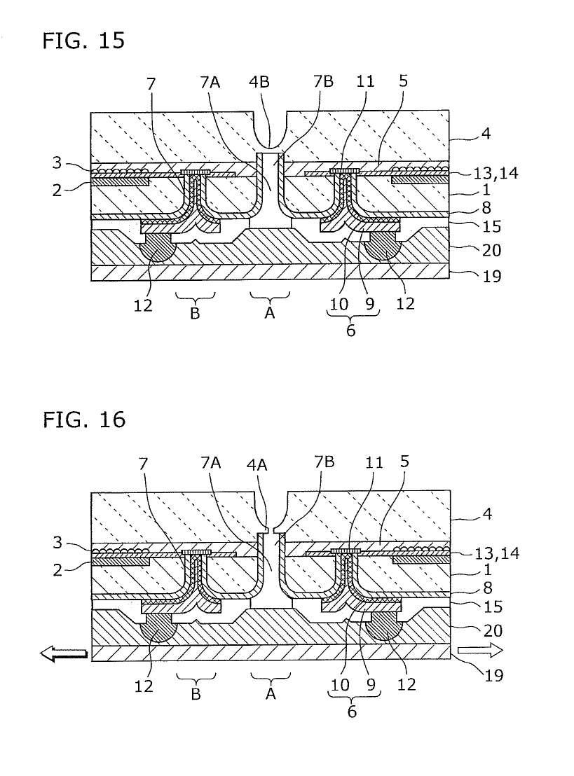

FIG. 15 and FIG. 18 illustrate the completed state of the dicing. Here, the portion of the light-transmissive substrate 4 constituting the bottom of the second through-groove 7B is thin as a result of the removal, and remains as a thin film 4B (the region of the light-transmissive substrate 4 that is continuous to the second through groove 7B).

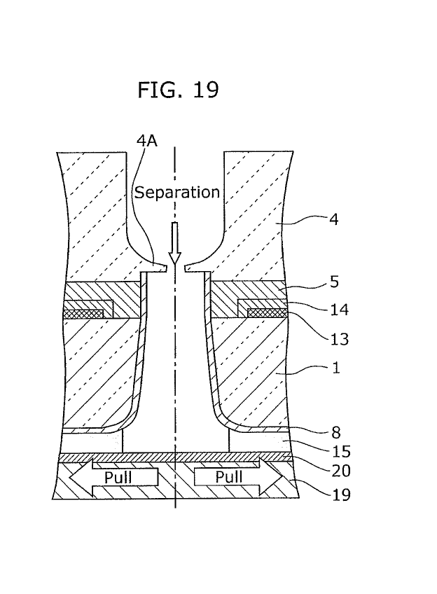

As shown in FIG. 16 and FIG. 19, a dicing sheet 19 is pulled outward. The light-transmissive substrate 4 is separated with the thin film 4B serving as an origin of the separation. In such a manner, the singulation is completed.

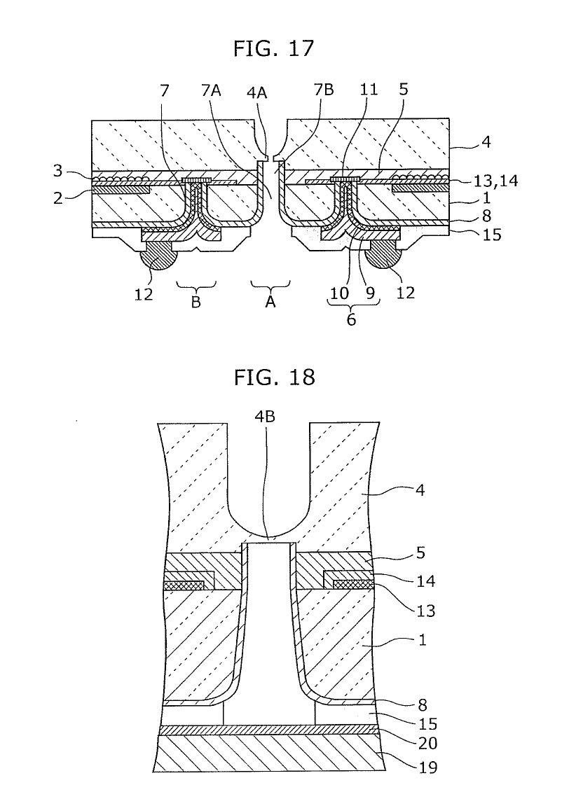

Lastly, as shown in FIG. 17, the dicing sheet 19 and the adhesive layer 20 are removed. In such a manner, a finished imaging device shown in FIG. 1 to FIG. 3B is manufactured.

For example, it is preferable to use, for the dicing blade 21, a blade that has a narrower width tip, so that the thin film 4B of the light-transmissive substrate 4 is thicker the farther it is from the center of the bottom of the second through-groove 7B. This reduces damages, caused by dicing, on the elements near the first through-groove 7A and the second through-groove 7B.

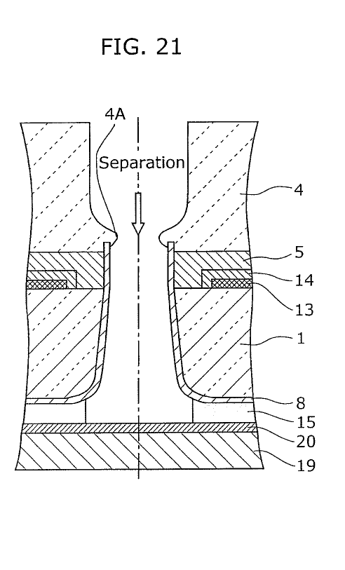

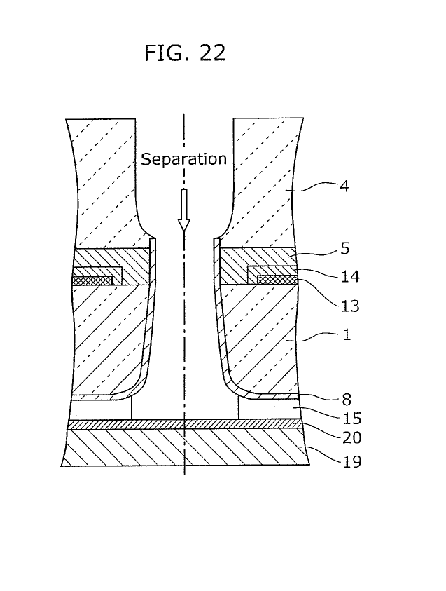

As shown in FIG. 16 and FIG. 19, when the dicing sheet 19 is pulled outward for the singulation, protruding (projecting) periphery 4A remains at the lateral sides of the light-transmissive substrate 4. The periphery 4A may cause a problem in handling or dropping of the imaging device at the time of secondary packaging or incorporating the imaging device into an electronic apparatus. To prevent this, it is preferable to separate the light-transmissive substrate 4 by illuminating laser on the thin film 4B for removing the thin film 4B. In this case, the width of a predetermined region of the thin film 4B removed by the separation is smaller than the width of the bottom of the second through-groove 7B. As a result, as shown in FIG. 21, the periphery 4A having a rounded shape is formed. Alternatively, it is preferable to separate the light-transmissive substrate 4 by performing dry etching or wet etching on the thin film 4B and removing the thin film 4B. In this case, the width of the predetermined region of the thin film 4B removed by the separation is substantially equivalent to that of the bottom of the second through-groove 7B. As a result, as shown in FIG. 22, the protruding periphery 4A is not formed.

In view of dicing property and compatibility to various kinds of separation methods of the light-transmissive substrate 4, it may be that the external electrodes 12 are formed after the singulation process shown in FIG. 16 and FIG. 19.

As described, according to the method of manufacturing the imaging device in the embodiment, it is possible to form the first through-groove 7A and the second through-groove 7B for the substrate separation at the same time of the formation of the through-electrode 6, by using the processes substantially same as that of conventional methods of manufacturing the through-electrodes. Accordingly, extra takt time and equipments relative to the conventional manufacturing processes are not very necessary. In addition, it is possible to obtain an imaging device with increased moisture prevention efficiency while reducing cost.

In the singulation process of the conventional method of manufacturing an imaging device, it is necessary to cut different materials that are a light-transmissive substrate, an adhesive layer, and a semiconductor substrate at once at the time of dicing. This imposes significant load on the blade, and easily generates dicing damage on the semiconductor substrate 1. Thus, compared to the case where dicing is performed only on the semiconductor substrate 1, it is necessary to reduce the dicing speed or to increase the scribe region, resulting in reduced productivity. In comparison, in the singulation process of the method of manufacturing the imaging device according to the embodiment, only the light-transmissive substrate 4 needs to be cut at the time of dicing. This imposes less load on the blade at the time of dicing, and reduces abrasion of the blade, thereby enabling longer period of use of the blade. Furthermore, the first through-groove 7A and the second through-groove 7B at the scribe region can have smaller width than the blade width; and thus, the scribe region can be narrower than that of a conventional imaging device. As a result, it is possible to obtain larger number of imaging devices from the large semiconductor substrate 1, allowing cost reduction.

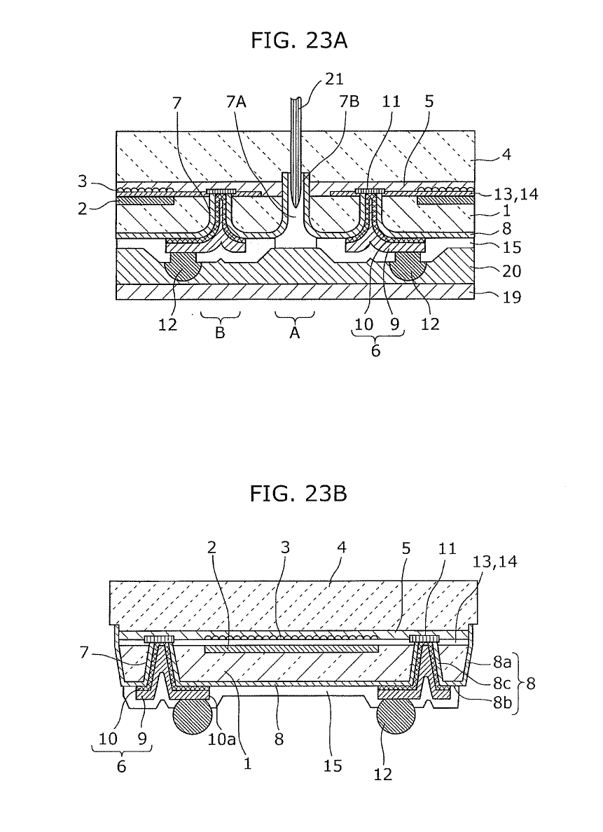

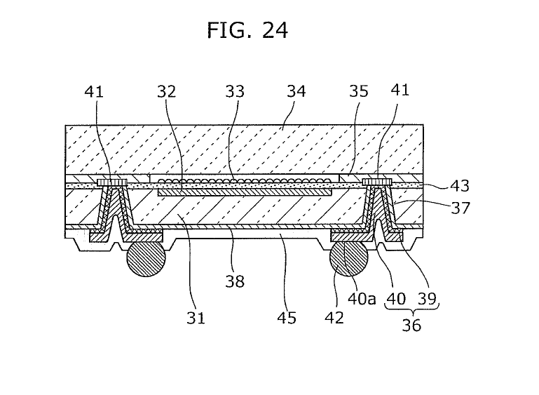

As shown in FIG. 23A, it may be that the width of the first through-groove 7A and the second through-groove 7B is equal to or greater than the blade width, and only the light-transmissive substrate 4 at the bottom of the second through-groove 7B is cut. According to this method, as shown in FIG. 23B, the protruding periphery 4A is not formed at the lateral surface of the light-transmissive substrate 4, which eliminates the need of the process of removing the protruding periphery 4A. Furthermore, the light-transmissive substrate 4 is formed slightly larger than the semiconductor substrate 1; and thus, it is possible to reduce influences of scattering light entering from the lateral surface of the light-transmissive substrate 4.

The semiconductor device and the method of manufacturing the semiconductor device according to the present invention have been described based on the embodiment; however, the present invention is not limited to the embodiment. Those skilled in the art will readily appreciate that various kinds of modifications are possible in the exemplary embodiments and other embodiments obtained by arbitrarily combining the structural elements in the embodiments are also possible without materially departing from the novel teachings and advantages of the present invention. Accordingly, all such modifications are intended to be included within the scope of this invention.

For example, when a moisture-resistant surface film with a low water absorption rate is formed on the lateral side of the adhesive layer 5, the insulating film 8 does not always need to be formed on the lateral side of the adhesive layer 5. Instead, a conductive film such as a metal film or any other inorganic material film may be formed on the lateral side of the adhesive layer 5. It is not always necessary that the insulating film 8 entirely covers the inner walls of the first through-groove 7A and the second through-groove 7B. Instead, it may be that a moisture resistant surface film is provided which covers the lateral surface of the adhesive layer 5 and is in close contact with at least part of the front surface or the lateral surface of the semiconductor substrate 1 near the first through-groove 7A and the second through-groove 7B and part of the front surface or the lateral surface of the protective plate.

It may also be that substrate contacts or thermal vias are provided in the recesses that are either penetrating or non-penetrating. For example, the present invention may be applied to diode elements or power amplifier elements other than the imaging elements. It may also be that the semiconductor substrate 1 does not include recesses. For example, the recesses for the through-electrodes are not necessary in the case where a lateral electrode or an external electrode running through a protective plate is provided or in the case where a protective plate is provided at the side of the semiconductor substrate 1 opposite to the side where the external electrode is formed.

In the embodiment, the imaging device has been used as an example as a semiconductor device according to the present invention; however, the semiconductor device according to the present invention is not limitative as long as the semiconductor device includes a protective plate fixed to the front surface of the semiconductor substrate via an adhesive layer. Thus, the present invention may be used for various types of semiconductor devices, such as an optical device, a memory, an LSI, and a discrete device, and for various types of electronic apparatus incorporating such semiconductor device, such as a mobile phone, a digital still camera, a camcorder, and a television.

Although only the exemplary embodiment of this invention has been described in detail above, those skilled in the art will readily appreciate that many modifications are possible in the exemplary embodiment without materially departing from the novel teachings and advantages of this invention. Accordingly, all such modifications are intended to be included within the scope of this invention.

### INDUSTRIAL APPLICABILITY

The present invention can be used for a semiconductor device and an electronic apparatus incorporating the semiconductor device, and in particular, to an optical device and an electronic apparatus, such as a digital camera and a camera phone, incorporating the optical device.

What is claimed is:

1. A semiconductor device comprising:
a semiconductor substrate;
a semiconductor layer provided in a front surface of said semiconductor substrate;
a protective plate provided above the front surface of said semiconductor substrate;
an adhesive layer provided between the front surface of said semiconductor substrate and a front surface of said protective plate, said adhesive layer fixing said protective plate to said semiconductor substrate; and
a first surface film covering a lateral surface of said adhesive layer, the lateral surface being not in contact with said protective plate and said semiconductor substrate,
wherein said first surface film continuously extends over the lateral surface of said adhesive layer onto said protective plate.

2. The semiconductor device according to claim 1,
wherein said semiconductor substrate includes a recess that is either penetrating or non-penetrating.

3. The semiconductor device according to claim 2,
wherein said recess is a hole.

4. The semiconductor device according to claim 1,
wherein said first surface film continuously extends over the lateral surface of said adhesive layer and said semiconductor substrate.

5. The semiconductor device according to claim 1,
wherein the front surface of said protective plate has a step that is lower than the front surface of said protective plate, and
said first surface film continuously extends over the lateral surface of said adhesive layer onto a surface and a lateral surface of said step.

6. The semiconductor device according to claim 4, further comprising
a second surface film provided on a back surface of said semiconductor substrate and bonded to said first surface film.

7. The semiconductor device according to claim 6,
wherein the back surface of said semiconductor substrate includes a recess that is either penetrating or non-penetrating, and
said semiconductor device further comprises
a third surface film that is provided on an inner wall of said recess and bonded to said second surface film.

8. The semiconductor device according to claim 6,
wherein said first surface film and said second surface film are integrally formed as a continuous film.

9. The semiconductor device according to claim 7,
wherein said second surface film and said third surface film are integrally formed as a continuous film.

10. The semiconductor device according to claim 4,
wherein said first surface film is chemically bonded to said semiconductor substrate.

11. The semiconductor device according to claim 1,
wherein said first surface film is chemically bonded to said protective plate.

12. The semiconductor device according to claim 1,
wherein said first surface film is an insulating film.

13. The semiconductor device according to claim 10,
wherein said first surface film is a silicon oxide film.

14. The semiconductor device according to claim 10,
wherein said semiconductor substrate is a silicon substrate.

15. The semiconductor device according to claim 11,
wherein said protective plate includes silicon.

16. The semiconductor device according to claim 1,
wherein an optical element is formed in said semiconductor layer, and
said protective plate is a light-transmissive substrate.

17. The semiconductor device according to claim 15,
wherein said protective plate is a silicate glass.

18. The semiconductor device according to claim 1, further comprising
an insulating layer provided on the front surface of said semiconductor substrate,
wherein said insulating layer has an opening at a peripheral surface of said semiconductor substrate.

19. The semiconductor device according to claim 1, further comprising
an insulating layer provided on the front surface of said semiconductor substrate, and including a plurality of films,
wherein a film, among the films of said insulating layer, has an opening at a peripheral surface of said semiconductor substrate.

20. The semiconductor device according to claim 2, further comprising a conductive film provided in said recess.

21. The semiconductor device according to claim 20,
wherein said recess is a through-hole penetrating said semiconductor substrate from the front surface to the back surface of said semiconductor substrate,
said semiconductor device further comprises
an electrode provided on the front surface of said semiconductor substrate and connected to said conductive film.

22. The semiconductor device according to claim 21,
wherein at least part of a surface of said electrode is in contact with said adhesive layer.

23. The semiconductor device according to claim 21, further comprising
an insulating layer provided on the front surface of said semiconductor substrate, and including a plurality of films,
wherein a film, among the films of said insulating layer, has an opening at a peripheral surface of said semiconductor substrate, the film being positioned at a level not lower than a level where said electrode is formed.

24. The semiconductor device according to claim 22, further comprising
an insulating layer provided on the front surface of said semiconductor substrate, and having an opening between said recess and said electrode.

25. The semiconductor device according to claim 23,
wherein at least one film, among the films of said insulating layer, has an opening at the peripheral surface of said semiconductor substrate, the at least one film being positioned at a level lower than the level where said electrode is formed.

26. The semiconductor device according to claim 24, further comprising
an insulating film provided between an inner wall of said recess and said conductive film, and bonded to said insulating layer.

27. The semiconductor device according to claim 18,
wherein said insulating layer is formed of a material having a property similar to a property of a material of said protective plate.

28. The semiconductor device according to claim 27,
wherein said insulating layer is formed of a silicon oxide film, and said protective plate is formed of a silicate glass.

29. The semiconductor device according to claim 1,
wherein said protective plate has a periphery protruding out from a lateral surface of said semiconductor substrate.

30. The semiconductor device according to claim 29,
wherein the periphery of said protective plate has a flat lateral surface.

31. The semiconductor device according to claim 1,
wherein said protective plate has a periphery that is thinner than a portion of said protective plate that is other than the periphery.

32. The semiconductor device according to claim 31,
wherein the periphery of said protective plate has a thickness which gradually decreases toward an edge of the periphery.

33. The semiconductor device according to claim 31,
wherein the periphery of said protective plate is provided above a peripheral surface of said semiconductor substrate.

34. An electronic apparatus comprising the semiconductor device that is according to claim 1.

35. A method of manufacturing a semiconductor device, said method comprising:
fixing a protective plate to a front surface of a semiconductor substrate via an adhesive layer, the front surface of the semiconductor substrate including a semiconductor layer; and
forming a first surface film on a lateral surface of the adhesive layer, the lateral surface being not in contact with the protective plate and the semiconductor substrate.

36. A method of manufacturing a semiconductor device, said method comprising:
fixing a protective plate to a front surface of a semiconductor substrate via an adhesive layer, the front surface of the semiconductor substrate including a plurality of semiconductor layers at a plurality of positions;
forming a first through-groove penetrating the semiconductor substrate from a back surface to the front surface of the semiconductor substrate;
forming a second through-groove by removing the adhesive layer at a bottom of the first through-groove, the second through-groove being continuous to the first through-groove and penetrating the adhesive layer from a front surface, of the adhesive layer, which is in contact with the semiconductor substrate to a back surface, of the adhesive layer, which is in contact with the protective plate; and
forming a first surface film on an inner wall of the second through-groove.

37. The method of manufacturing a semiconductor device according to claim 35, further comprising
thinning the semiconductor substrate to which the protective plate is fixed.

38. The method of manufacturing a semiconductor device according to claim 36, further comprising
thinning the semiconductor substrate to which the protective plate is fixed,
wherein said thinning is performed before said forming of a first through-groove.

39. The method of manufacturing a semiconductor device according to claim 35,
wherein, in said forming of a first surface film, a second surface film is formed on a back surface of the semiconductor substrate at the same time of forming the first surface film.

40. The method of manufacturing a semiconductor device according to claim 35, further comprising
forming, in the semiconductor substrate, a recess that is either penetrating or non-penetrating.

41. The method of manufacturing a semiconductor device according to claim 36,
wherein, in said forming of a first through-groove, a recess that is either penetrating or non-penetrating is formed in the semiconductor substrate at the same time of forming the first through-groove.

42. The method of manufacturing a semiconductor device according to claim 40,
wherein, in said forming of a first surface film, a third surface film is formed on an inner wall of the recess at the same time of forming the first surface film.

43. The method of manufacturing a semiconductor device according to claim 40, further comprising:
forming an insulating layer on the front surface of the semiconductor substrate and forming an electrode on the insulating layer; and
forming an opening at a portion of the insulating layer between the recess and the electrode, before said forming of a first surface film.

44. The method of manufacturing a semiconductor device according to claim 41, further comprising:
forming an insulating layer on the front surface of the semiconductor substrate, and forming an electrode on the insulating layer; and
forming an opening at a portion of the insulating layer between the recess and the electrode, before said forming of a first surface film and after said forming of a second through-groove.

45. The method of manufacturing a semiconductor device according to claim 35, further comprising
forming a step in a front surface of the protective plate by removing part of the protective plate,
wherein, in said forming of a first surface film, the first surface film is formed so as to continuously extend over the adhesive layer onto the step.

46. The method of manufacturing a semiconductor device according to claim 44,
wherein, in said forming of an opening, a step is formed in a front surface of the protective plate by removing the protective plate at a bottom of the second through-groove, at the same time of forming the opening of the insulating layer,

47. The method of manufacturing a semiconductor device according to claim 37, further comprising:
separating the protective plate at a position that is continuous to the second through-groove, after said forming of a first surface film.

48. The method of manufacturing a semiconductor device according to claim 47,
wherein, in said separating, the protective plate is separated by removing the protective plate at the position that is continuous to the second through-groove such that a width of a removed portion of the protective plate is narrower than a width of a bottom of the second through-groove.

49. The method of manufacturing a semiconductor device according to claim 47, further comprising:
removing part of the protective plate at the position which is continuous to the second through-groove and which is opposite to an adhesion side of the protective plate,
wherein, in said separating, the protective plate is separated with a portion of the protective plate as an origin of the separation, the portion being thinned by said removing.

50. The method of manufacturing a semiconductor device according to claim 49,
wherein, in said removing, the part of the protective plate is removed such that a width of a removed region of the protective plate is greater than a width of a bottom of the second through-groove.

51. The method of manufacturing a semiconductor device according to claim 49,
wherein, in said separating, the protective plate is separated by illuminating laser on the portion, of the protective plate, which is thinned by said removing.

52. The method of manufacturing a semiconductor device according to claim 49,
wherein, in said separating, the protective plate is separated by etching the portion, of the protective plate, which is thinned by said removing.

53. The method of manufacturing a semiconductor device according to claim 52,
wherein, in said separating, the protective plate is separated such that a width of a portion, of the protective plate, removed by said separating is substantially equivalent to a width of the bottom of the second through-groove.
